(19) United States
(12) Patent Application Publication
(10) Pub. No.: US 2010/0264022 A1
(43) Pub. Date: Oct. 21, 2010

(54) Sputtering And Ion Beam Deposition

(75) Inventors: Mun-Sik Chim, Suwon-si (KR); Joong-Whan An, Yongin-si (KR)

Correspondence Address: REINHART BOERNER VAN DEUREN P.C., 2215 PERRYGREEN WAY, ROCKFORD, IL, 61107, US

(73) Assignee: Mun-Sik Chim, Suwon-si (KR)

(21) Appl. No.: 12/744,640

(22) PCT Filed: Oct. 17, 2008
(86) PCT No.: PCT/KR08/06139

§ 371 Date: May 25, 2010

(30) Foreign Application Priority Data
Nov. 28, 2007 (KR) 10-2007-0121969

(51) Int. Cl. C23C 14/35

(52) U.S. Cl. 204/298.04

(57) ABSTRACT

An apparatus for depositing an oxide thin film using sputtering and ion beam deposition includes a metal target (made of Nb or Si) installed on the wall of a chamber, an ion source gun for improving properties of an optical thin film, and a substrate installed on a drum jig in the center of the chamber, thereby enabling a high-quality optical thin film to be deposited in the chamber at temperature of 60° C.±5° C. The apparatus includes a chamber in which a substrate holder drum is installed, a substrate mounted on the substrate holder drum, metal targets installed on opposite outer walls of the chamber so as to deposit a metal thin film onto the substrate, and an ion source gun installed on the chamber and generating oxygen ions for oxidizing the metal thin film.

### TECHNICAL FIELD

The present invention relates to an apparatus for depositing an oxide thin film using sputtering and ion beam deposition, and more particularly, to an apparatus for depositing an oxide thin film, which includes a metal target (made of Nb or Si) installed on the wall of a chamber, an ion source gun for improving properties of an optical thin film, and a drum jig in the center of the chamber on which a substrate is placed, thereby enabling a high-quality optical thin film to be deposited at a chamber temperature of 60° C.±5° C.

### BACKGROUND ART

In general, optical thin-film deposition ejects a material to be deposited using a thermal resistance method or an electron gun under vacuum, and thereby deposits it onto a substrate. The thin film deposited on the substrate in a non-equilibrium state at a low temperature has a columnar structure including voids. As such, packing density defined by a ratio of a volume of the rest, a column part, other than the voids of the thin film to a volume summing up the voids and the column part of the thin film has a value still lower than 1 that is the packing density in a bulk state.

After coated under vacuum, the thin film having this structure is exposed to the air. In this case, the voids of the thin film absorb moisture in the air. As a result, the thin film is subjected to a change in refractive index as well as reduction in hardness and adhesive force, and has an absorption band at a specific wavelength region. Further, the thin film undergoes a change in optical thickness with the lapse of time, and thus a shift of its wavelength region.

Further, since the thin film frequently has non-uniform refractive index distribution and an anisotropic crystal structure, this thin film shows a great difference as compared to a uniform and isotropic thin film assumed when a multilayered thin film is designed.

Conventionally, when an oxide thin film is deposited without an ion source by sputtering, oxygen reaction gas is generated injected into the proximity of the metal target. This injection of the oxygen reaction gas reduces a deposition rate due to oxidation of the metal target, generates arc from the metal target, makes it difficult to precisely control a deposition thickness, and increases temperature of a product.

For this reason, in order to fabricate a high-quality optical thin film using sputtering, a method of fabricating an oxide thin film by depositing a metal thin film having high packing density and by supplying oxygen reaction gas to ion beams is required.

In the journal vols. 43 (2000) and 42 (1999) of Society of Vacuum Coaters, it was disclosed that closed drift ion sources could be applied to diamond-like carbon (DLC) coating, plastic coating, and optical coating.

However, in the same journal vol. 43 (2000), it was disclosed that, when an optical thin film was actually fabricated, arc was generated from a substrate due to excessive positive ions, and thus has a great influence on quality of a product, so that the arc made it difficult to deposit the oxide thin film.

Further, US patent titled PROCESS FOR DEPOSITION OPTICAL FIDE ON BON PLANAR AND NON-PLANAR SUBSTRATES and issued on Jul. 6, 1993 disclosed that the optical films are fabricated in multiple layers using Ta₂O₅/SiO₂.

However, in this method, an anode is not separately installed on a chamber, and thus the chamber functions as the anode. As such, during the deposition of the multilayered oxide thin film, the anode is consumed, and thus plasma is unstable. Further, since a magnet for increasing plasma density of an ion source gun is separated from an anode of the ion source gun, an electric field is dispersed up and down, which results in reducing efficiency. As such, the oxygen reaction gas is further required. Further, since the anode is exposed, the multilayered thin film is easily contaminated when deposited, and thus the plasma becomes unstable.

In addition, when the oxide thin film is deposited by sputtering, an oxide target may be used. This use of the oxide target increases price and temperature of a target to make it impossible to scale up the target. As a result, the costs of deposition equipment are increased.

### DISCLOSURE

### Technical Problem

The present invention has been made to solve the foregoing problems with the prior art, and embodiments of the present invention provide an apparatus for depositing an oxide thin film using a high-efficiency ion source gun and high-quality sputtering and ion beam deposition, which maintains deposition temperature of room temperature when multiple optical thin films are deposited, provides a high deposition rate, removes generation of arc of a target, and does not add any device for precise deposition thickness control.

### Technical Solution

According to an aspect of the present invention, there is provided an apparatus for depositing an oxide thin film using sputtering and ion beam deposition. The apparatus includes: a chamber in which a substrate holder drum is installed; a substrate mounted on the substrate holder drum; metal targets installed on opposite outer walls of the chamber so as to deposit a metal thin film onto the substrate; and an ion source gun installed on the chamber and generating oxygen ions for oxidizing the metal thin film, wherein the ion source gun includes an outer cathode, an inner cathode, an anode between the outer and inner cathodes, and at least one magnet installed to the anode.

In an embodiment of the present invention, the magnet may be mounted inside the anode of the ion source gun.

In another embodiment of the present invention, the anode of the ion source gun may have a conductor placed above and in contact with the magnet.

In another embodiment of the present invention, the ion source gun may have an insulator so that the anode is located on the insulator, spaced apart from the magnet.

In another embodiment of the present invention, the ion source gun may be configured so that each of the outer and inner cathodes maintains an angle of 45°±10° with respect to the magnet.

In another embodiment of the present invention, the ion source gun may be configured so that a distance between the anode and the inner cathode and a distance between the anode and the outer cathode each maintain 10±8 mm.

In another embodiment of the present invention, the ion source gun may be configured so that a distance between the magnet and the inner cathode and a distance between the magnet and the outer cathode each maintain 15±8 mm.

In another embodiment of the present invention, the ion source gun may be configured so that gas (oxygen (O₂)) is injected into opposite sides of the anode.

### ADVANTAGEOUS EFFECTS

As set forth above, the apparatus for depositing an oxide thin film using sputtering and ion beam deposition can provide a high deposition rate, reduce arc generated by oxidation of the metal target, and precisely control a deposition thickness due to stable cathode voltage of the metal target.

### DESCRIPTION OF DRAWINGS

FIG. 1 schematically illustrates an apparatus for depositing an oxide thin film according to an embodiment of the present invention;

FIG. 2 is a detailed view illustrating a metal target according to an embodiment of the present invention;

FIG. 3 is a detailed view illustrating an ion source gun according to a first embodiment of the present invention;

FIG. 4 is a detailed view illustrating an ion source gun according to a second embodiment of the present invention;

FIG. 5 is a detailed view illustrating an ion source gun according to a third embodiment of the present invention;

FIG. 6 is a graph showing the results measuring energy (eV) depending on a change in the anode current of an ion source gun according to a first embodiment of the present invention;

FIGS. 7 and 8 are graphs showing the results measuring ion density depending on a change in the anode current of an ion source gun.

FIG. 9 is a graph showing the transmittance characteristic of an oxide thin film of Nb₂O₅ depending on a change in the flow rate of oxygen reaction gas;

FIG. 10 is a graph showing the refractive index of an oxide thin film of Nb₂O₅ depending on a change in the flow rate of oxygen reaction gas;

FIG. 11 is a graph showing the absorption coefficient of an oxide thin film of Nb₂O₅ depending on a change in the flow rate of oxygen reaction gas;

FIG. 12 is a graph showing the composition of an oxide thin film of Nb₂O₅, which is analyzed by x-ray photoelectron spectroscopy (XPS); and

FIG. 13 shows spectroscopic analysis spectrums of Nb₂O₅ and SiO₂ layers, in which the Nb₂O₅ and SiO₂ layers are alternately deposited 32 times.

### MAJOR REFERENCE NUMERALS AND SYMBOLS OF THE DRAWINGS

1: chamber 2: metal target (Nb)
3: pump 4: ion source gun
5: Faraday cup 6: metal target (Si)
7: drum jig 8: chamber door
9: crystal thickness monitor
10: anode 11: outer wall cover
12: fixing cover 13: metal target
14: target power 15: target anode
16: magnet 17: outer wall
18: anode 19: insulator
20: support plate 21: gas injection port
22: inner wall 23: inner cathode
24: outer cathode 25: insulator

### BEST MODE

Hereinafter, an apparatus for depositing an oxide thin film using sputtering and ion beam deposition according to an embodiment of the present invention will be described in detail with reference to the accompanying drawings.

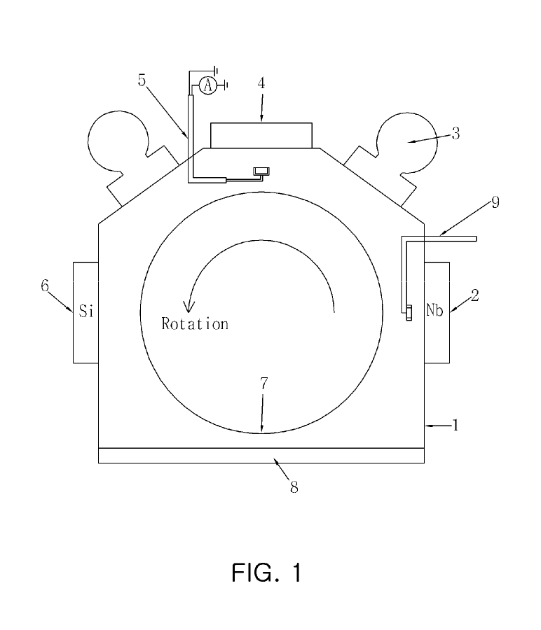

In the accompanying drawings, FIG. 1 schematically illustrates an apparatus for depositing an oxide thin film according to an embodiment of the present invention. Referring to FIG. 1, the apparatus for depositing an oxide thin film according to an embodiment of the present invention includes a chamber 1 in which a substrate holder drum 7 is installed, a substrate (not shown) mounted on the substrate holder drum 7, metal targets 2 and 6 installed on opposite outer walls of the chamber 1 so as to deposit a metal thin film (of Nb or Si) onto the substrate, and an ion source gun 4 installed on the chamber 1 and generating oxygen ions for oxidizing the metal targets 2 and 6.

As illustrated in FIG. 1, the apparatus for depositing an oxide thin film further includes at least one pump 3, which is for maintaining the chamber 1 under vacuum between the metal targets 2 and 6 and the ion source gun 4. A reference number 8 indicates a door for the chamber. Further, a reference number 9 indicates a crystal thickness monitor, which controls a thickness of the deposited thin film. The thickness of the deposited thin film is monitored through the crystal thickness monitor 9. Thereby, a desired thickness of the deposited thin film is controlled.

According to an embodiment of the present invention, the apparatus for depositing an oxide thin film deposits the metal thin film (of Nb or Si) onto the substrate using the metal target 2 or 6. Here, when the substrate mounted on the substrate holder drum 7 is rotated, the metal thin film (of Nb or Si) approaches the ion source gun. Then, the ion source gun 4 generates oxygen ions to oxidize the metal thin film (of Nb or Si). At this time, by increasing efficiency of the ion source gun 4, an amount of supplied oxygen is reduced to prevent oxidation of the metal target 2 or 6.

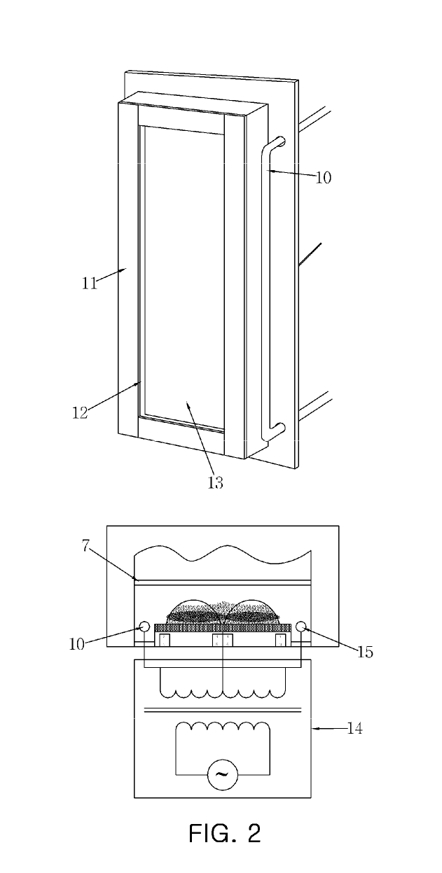

In the accompanying drawings, FIG. 2 is a detailed view illustrating a metal target according to an embodiment of the present invention. The metal target acts as a cathode for sputtering, and includes target anodes 10 and 15, an outer wall cover 11, a fixing cover 12, a metal target 13, a power supply 14 (e.g. 40 kHz AC power supply). The metal target 13 of FIG. 2 corresponds to the metal target 2 or 6 of FIG. 1.

Here, the power supply 14 (e.g. 40 kHz AC power supply) supplies sine-wave power to the metal target 13 and the target anodes 10 and 15 located on opposite sides of the metal target 13. In this case, the power is supplied so as to generate plasma between the target anode 10 and the metal target 13 first, and then between the target anode 15 and the metal target 13.

This configuration serves to prevent unstable plasma caused by ion accumulation on the oxide thin film when the metal target 13 reacts with the oxygen reaction gas to form the oxide thin film.

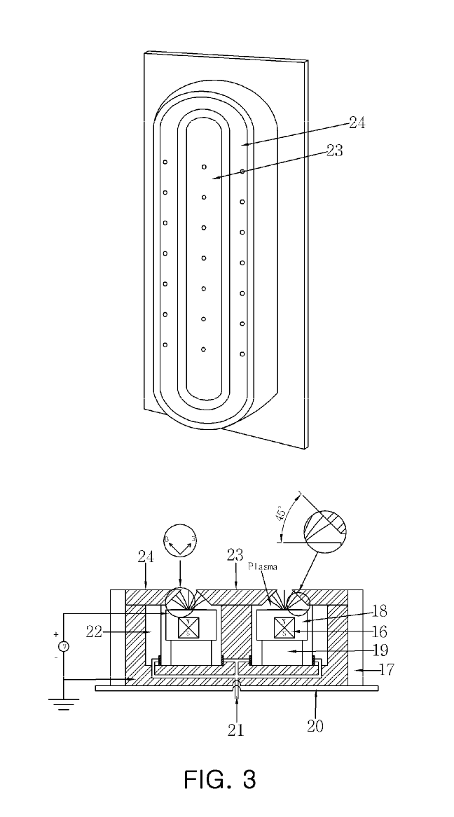

In the accompanying drawings, FIG. 3 is a detailed view illustrating an ion source gun according to a first embodiment of the present invention.

Referring to FIG. 3, the ion source gun 4 (see FIG. 1) includes a case 17, a support plate 20 supporting a lower portion of the case 17, an outer cathode 24 located inside the case 17, an inner cathode 23 enclosed by the outer cathode 24, an inner wall 22 formed inside the outer cathode 24, an insulator 19 installed on the bottom of an internal space between the outer cathode 24 and the inner cathode 23, and an anode 18 installed on the insulator 19 with at least one magnet 16 embedded therein. The ion source gun 4 further includes a gas injection port 21 for injecting the oxygen reaction gas.

Here, the oxygen reaction gas is injected between the anode 18 and the two cathodes 23 and 24, thereby generating the plasma on the side of the anode 18. The magnet 16 embedded in the anode 18 forms a strong magnetic field between the anode 18 and the two cathodes 23 and 24 to thereby increase density of the plasma. Further, the magnet 16 inhibits voltage of the anode 18 from being increased, thereby preventing arc from being generated due to accumulation of cations on the substrate.

Meanwhile, in order to increase the density of the magnetic field, improve the efficiency of the ion source gun, and minimize exposure of the anode, two magnets 16 are used to form a circuit, so that contamination can be reduced during the deposition of the multilayered thin film.

Here, each of the outer cathode 24 and the inner cathode 23 of the ion source gun is preferably designed to maintain an angle of 45°±10° with respect to the magnet 16.

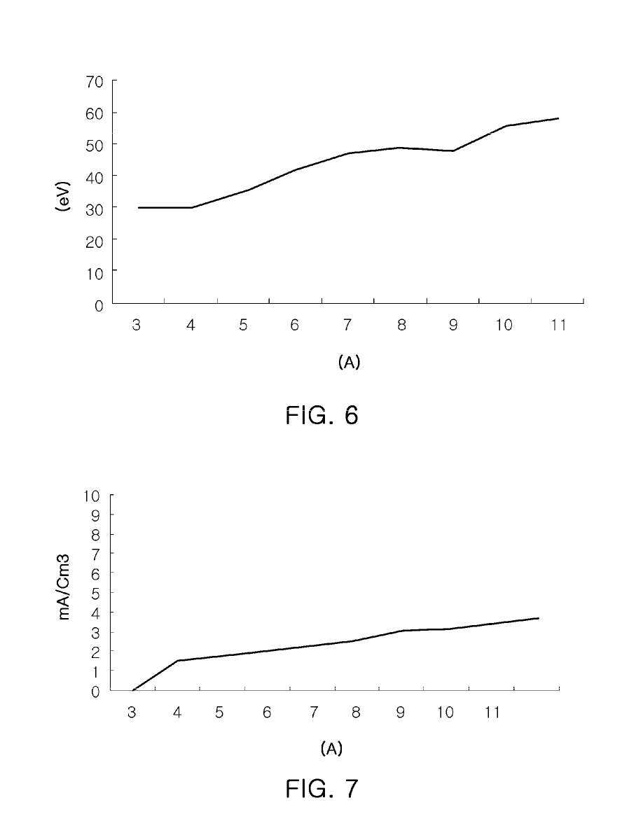

Table 1 below and FIG. 6 show the results measuring energy (eV) depending on a change in anode current of the ion source gun of FIG. 3 according to a first embodiment of the present invention. The measurement was carried out using a faraday cup 5 (see FIG. 1) under conditions: distance of 100 mm between the ion source gun 4 and the faraday cup 5 (see FIG. 1); process pressure of 2×10⁻³ Torr; and flow rate of 220 sccm of argon (Ar) injected into the ion source gun.

TABLE 1

| Anode Current of Ion Source Gun (A) | Energy (eV) |
|---|---|
| 3 | 30 |
| 4 | 30 |
| 5 | 35 |
| 6 | 42 |
| 7 | 47 |
| 8 | 49 |
| 9 | 48 |
| 10 | 56 |
| 11 | 58 |

Referring to FIG. 6, when the anode current of the ion source gun is 3A, the energy represents 30 eV. When the anode current of the ion source gun is higher than 7A, the energy represents 47 eV. Here, it can be found that the energy represents 60 eV or less although the anode current of the ion source gun is greatly increased.

Table 2 below and FIG. 7 show the results measuring anode voltage change and ion density depending on a change in the anode current of an ion source gun.

TABLE 2

| Anode Current of Ion | Anode Voltage of Ion | |
|---|---|---|
| Source Gun (A) | Source Gun (V) | Ion Density (mA/cm³) |
| 3 | 82 | 1.59 |
| 4 | 85 | 1.8 |
| 5 | 85 | 2.1 |
| 6 | 89 | 2.38 |
| 7 | 91 | 2.61 |
| 8 | 91 | 3.1 |
| 9 | 90 | 3.17 |
| 10 | 90 | 3.4 |
| 11 | 94 | 3.69 |

As in FIG. 6, the measurement was carried out under conditions: distance of 100 mm between the ion source gun and the faraday cup; process pressure of 2×10⁻³ Torr; and flow rate of 220 sccm of Ar injected into the ion source gun. When the anode current of the ion source gun is 3A, the anode voltage of the ion source gun represents 82V, and the ion density represents 1.59 mA/cm³. When the anode current of the ion source gun is 7A, the anode voltage of the ion source gun represents 91V, and the ion density represents 2.61 mA/cm³.

Here, it can be found that the ion density is greatly increased as the anode current of the ion source gun increases. However, a rate at which the anode voltage of the ion source gun is increased depending on the change in the anode current of the ion source gun is not great, and the anode voltage of the ion source gun represents 100V or less. This can prevent the arc from being generated due to excessive ions accumulated on the substrate.

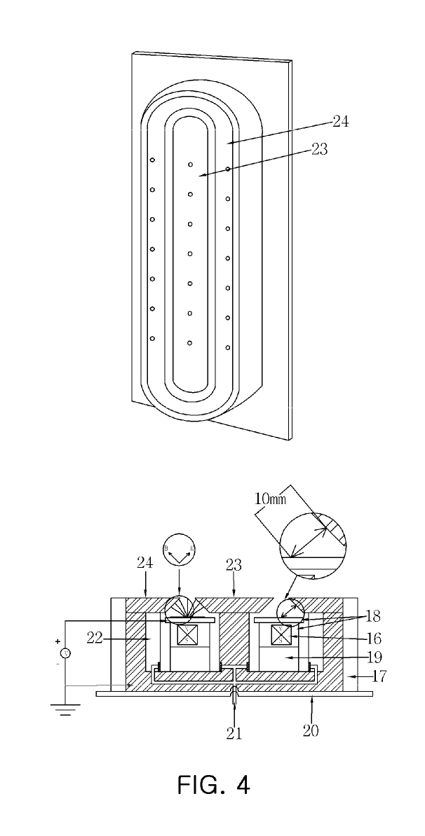

In the accompanying drawings, FIG. 4 is a detailed view illustrating an ion source gun according to a second embodiment of the present invention. Referring to FIG. 4, the ion source gun has a structure in which an anode 18 has a conductor placed above and in contact with a magnet 16.

A test was made under the same conditions as in Table 2 (process pressure of 2×10³ Torr, and Ar flow rate of 220 sccm). The test showed that the anode voltage and ion density of the ion source gun had the same results. The same results were based on no change in intensity of the magnetic field.

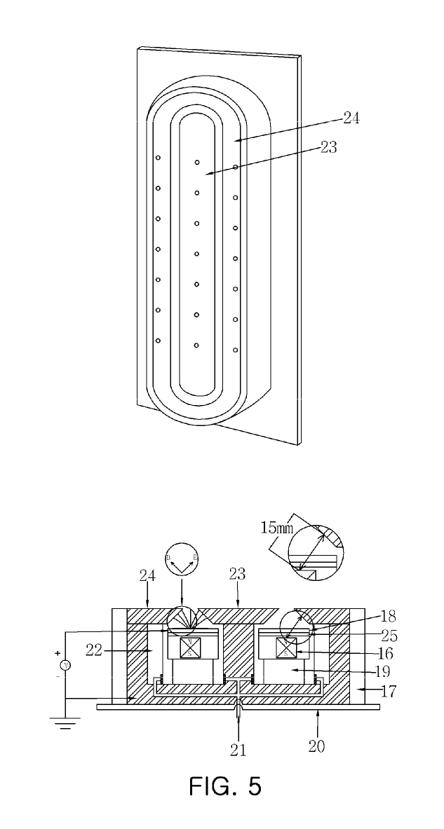

In the accompanying drawings, FIG. 5 is a detailed view illustrating an ion source gun according to a second embodiment of the present invention. Referring to FIG. 5, the ion source gun has a structure in which an insulator 25 is spaced apart from a magnet 16, and an anode 18 is formed on the insulator 25. A reference number 19 indicates an insulator that electrically isolates the anode 18 from cathodes 23 and 24.

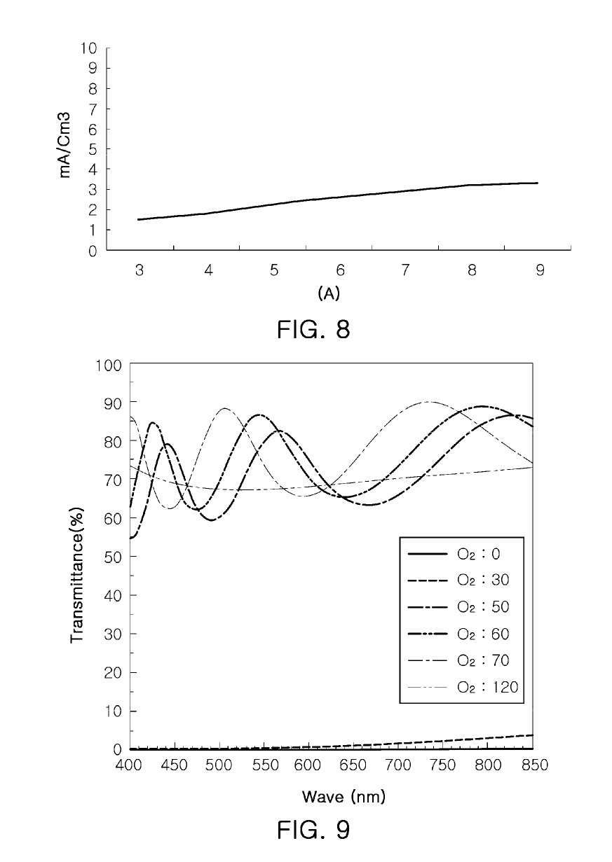

Table 3 below and FIG. 8 show the results measuring ion density depending on a change in the anode current of an ion source gun. A test was made with the insulator 25 having a thickness of 1 mm interposed between the magnet 16 and the anode 18 of the ion source gun.

TABLE 3

| Anode Current of Ion | Anode Voltage of Ion | |
|---|---|---|
| Source Gun (A) | Source Gun (V) | Ion Density (mA/cm³) |
| 3 | 86 | 1.5 |
| 4 | 88 | 1.78 |
| 5 | 90 | 2.3 |
| 6 | 91 | 2.65 |
| 7 | 93 | 2.9 |
| 8 | 93 | 3.2 |
| 9 | 96 | 3.3 |

The test was made under the same conditions: process pressure of 2×10⁻³ Torr; and Ar flow rate of 220 sccm). When the anode current of the ion source gun is 3A, the anode voltage of the ion source gun represents 86V, and the ion density represents 1.5 mA/cm³. When the anode current of the ion source gun is 6A, the anode voltage of the ion source gun represents 91V, and the ion density represents 2.65 mA/cm³.

Thus, it is shown that the anode voltage and ion density of the ion source gun are not greatly changed.

In the accompanying drawings, FIG. 9 is a graph showing the transmittance characteristic of an oxide thin film of Nb₂O₅ depending on a change in the flow rate of oxygen reaction gas, and particularly shows a spectroscopic analysis spectrum of the oxide thin film of Nb₂O₅, which is deposited with power of 4.5 kW for 10 minutes. As shown in FIG. 9, the test was made when flow rates of oxygen reaction gas were 0 sccm, 30 sccm, 50 sccm, 60 sccm, 70 sccm and 120 sccm. When the flow rates of oxygen reaction gas were 0 sccm and 30 sccm, the metal target (Nb) was deposited due to shortage of the oxygen reaction gas. This deposition brings about absorption of light, and thus the transmittance of Nb₂O₅ was 5% or less.

When the flow rate of oxygen reaction gas was 120 sccm, the deposition thickness was thin due to high pressure in the chamber and oxidation of the metal target (Nb). Thus, the envelope had only one minimum value. It could be found that the transmittance characteristic was highest at 70 sccm.

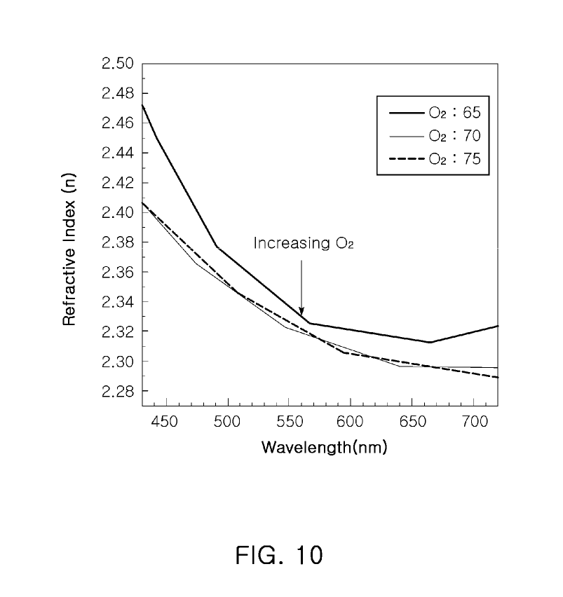

In the accompanying drawings, FIG. 10 is a graph showing the refractive index of an oxide thin film of Nb₂O₅ depending on a change in the flow rate of oxygen reaction gas, and particularly shows refractive indices of 2.43, 2.39, and 2.387 (wavelength λ=450 nm) when the flow rates of oxygen reaction gas are 65 sccm, 70 sccm, and 75 sccm.

Referring to FIG. 10, it can be found that, as an amount of oxygen increases, a refractive index decreases. This result makes it possible to expect that a deposition rate is reduced due to oxidation of the metal target (Nb), and that packing density of the oxide thin film is reduced due to an increase in the process pressure.

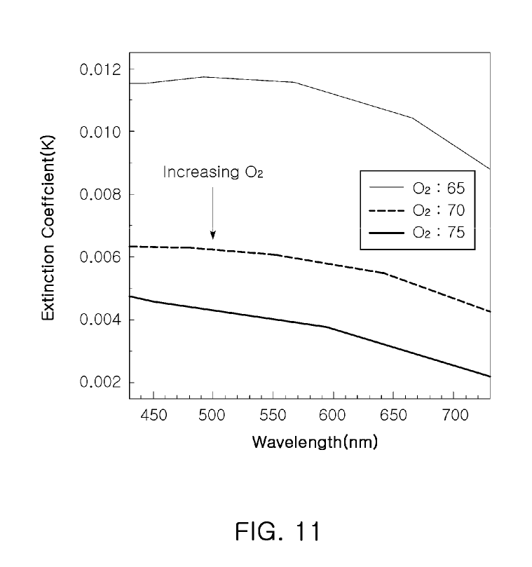

In the accompanying drawings, FIG. 11 is a graph showing the absorption coefficient of an oxide thin film of Nb₂O₅ depending on a change in the flow rate of oxygen reaction gas, and particularly shows how an extinction coefficient of the oxide thin film of Nb₂O₅ is varied depending on an increase in the flow rate of oxygen reaction gas when the oxide thin film of Nb₂O₅ is deposited. Referring to FIG. 11, the extinction coefficients of the oxide thin film of Nb₂O₅ are 0.0115, 0.0060 and 0.0041 (wavelength λ=450 nm) when the flow rates of oxygen reaction gas are 65 sccm, 70 sccm, and 75 sccm.

It can be found that, as the oxygen reaction gas increases, the extinction coefficient decreases. Further, the extinction coefficient when the flow rate of oxygen reaction gas is 65 sccm shows a great difference, as compared to that when the flow rate of oxygen reaction gas is 70 sccm.

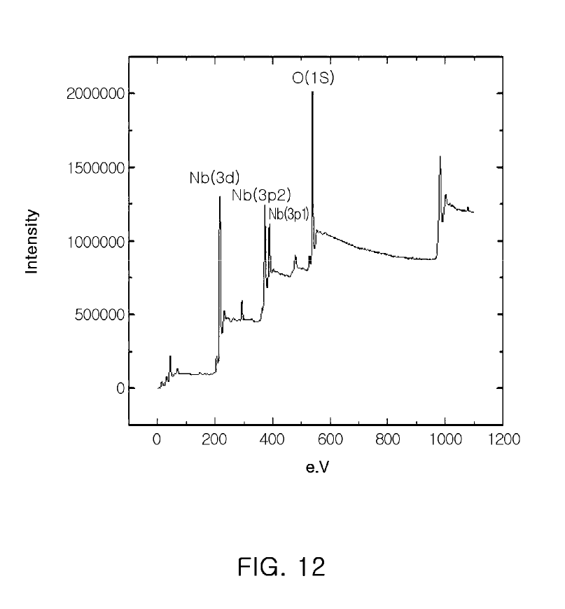

In the accompanying drawings, FIG. 12 is a graph showing the composition of an oxide thin film of Nb₂O₅, which is analyzed by x-ray photoelectron spectroscopy (XPS), and particularly shows results analyzing chemical bond energy and composition of the oxide thin film of Nb₂O₅. The energies of orbital electrons emitted from elements composing the oxide thin film of Nb₂O₅ were measured by the analysis method of XPS.

Here, the X axis indicates energy expressed by eV, and the Y axis indicates intensity. Further, the flow rate of oxygen reaction gas is 70 sccm. It can be seen from the test results that the thin film has the same test results as that of a bulk state. The peak of the intensity shows when the energy is 207 eV and 210 eV. Thus, it can be found that the oxide thin film of Nb₂O₅ is formed.

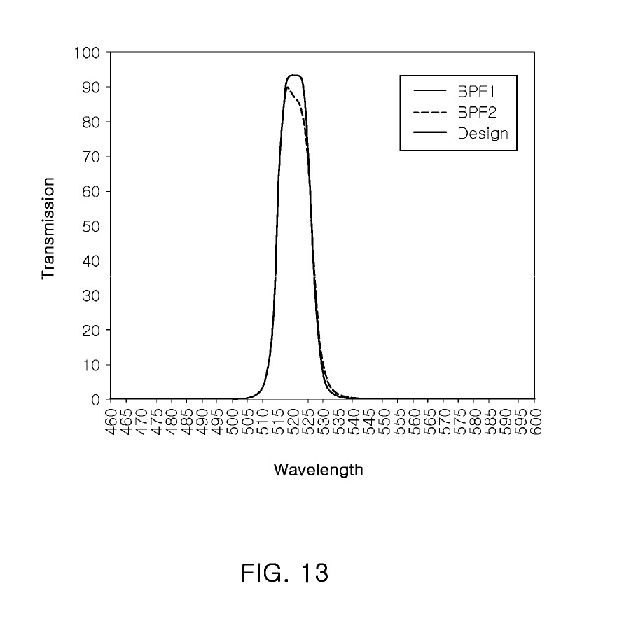

Table 4 below and FIG. 13 of the accompanying drawings show spectroscopic analysis spectrums of Nb₂O₅ and SiO₂ layers, in which the Nb₂O₅ and SiO₂ layers are alternately deposited 32 times. At this time, Nb₂O₅ (n=2.38, and λ=460 nm), SiO₂ (n=1.46, and λ=460 nm), and a substrate (glass, and n=1.520) are used, and detailed deposition conditions are as follows.

TABLE 4

| | | | Extinction | Physical |
|---|---|---|---|---|
| Layer | Materials | Refractive Index | Coefficient | Thickness(nm) |
| Substrate | Glass | 1.52031 | 0 | |
| 1 | Nb₂O₅ | 2.38922 | 0 | 54.41 |
| 2 | SiO₂ | 1.46132 | 0 | 88.96 |
| 3 | Nb₂O₅ | 2.38922 | 0 | 54.41 |
| 4 | SiO₂ | 1.46132 | 0 | 88.96 |
| 5 | Nb₂O₅ | 2.38922 | 0 | 108.82 |
| 6 | SiO₂ | 1.46132 | 0 | 88.96 |
| 7 | Nb₂O₅ | 2.38922 | 0 | 54.41 |
| 8 | SiO₂ | 1.46132 | 0 | 88.96 |
| 9 | Nb₂O₅ | 2.38922 | 0 | 54.41 |
| 10 | SiO₂ | 1.46132 | 0 | 88.96 |
| 11 | Nb₂O₅ | 2.38922 | 0 | 54.41 |
| 12 | SiO₂ | 1.46132 | 0 | 88.96 |
| 13 | Nb₂O₅ | 2.38922 | 0 | 54.41 |
| 14 | SiO₂ | 1.46132 | 0 | 88.96 |
| 15 | Nb₂O₅ | 2.38922 | 0 | 108.82 |
| 16 | SiO₂ | 1.46132 | 0 | 177.92 |
| 17 | Nb₂O₅ | 2.38922 | 0 | 108.82 |
| 18 | SiO₂ | 1.46132 | 0 | 88.96 |
| 19 | Nb₂O₅ | 2.38922 | 0 | 54.41 |
| 20 | SiO₂ | 1.46132 | 0 | 88.96 |
| 21 | Nb₂O₅ | 2.38922 | 0 | 54.41 |
| 22 | SiO₂ | 1.46132 | 0 | 88.96 |
| 23 | Nb₂O₅ | 2.38922 | 0 | 54.41 |
| 24 | SiO₂ | 1.46132 | 0 | 88.96 |
| 25 | Nb₂O₅ | 2.38922 | 0 | 54.41 |
| 26 | SiO₂ | 1.46132 | 0 | 88.96 |
| 27 | Nb₂O₅ | 2.38922 | 0 | 108.82 |
| 28 | SiO₂ | 1.46132 | 0 | 88.96 |
| 29 | Nb₂O₅ | 2.38922 | 0 | 54.41 |
| 30 | SiO₂ | 1.46132 | 0 | 88.96 |
| 31 | Nb₂O₅ | 2.38922 | 0 | 54.41 |
| 32 | SiO₂ | 1.46132 | 0 | 88.96 |
| Medium | Air | 1 | 0 | |
| Total | | | | 2600.55 |
| Thickness | | | | |

TABLE 5

| | Nb₂O₅ | SiO₂ |
|---|---|---|
| Substrate Temperature | 60° C. | 60° C. |
| Work Vacuum | 0.8 mTorr | 0.7 mTorr |
| Rotational Speed (rpm) | 60 | 60 |
| Substrate Size (mm) | 104.5 × 51 | 104.5 × 51 |
| Deposition Rate (Å/sec) | 3.2 (Nb) | 4 (Si) |
| Oxygen Reaction Gas | 70 sccm | 60 sccm |
| Sputter Power | 4 kW | 3.8 kW |
| Base Vacuum | 3.0 × 10⁻⁶ Torr | 3.0 × 10⁻⁶ Torr |
| Anode Current of Ion Source | 4.0 A | 3 A |
| Gun | | |

Table 5 represents the deposition conditions of the Nb₂O₅ and SiO₂ layers. As can be seen from Table 5, the substrate temperatures during deposition do not rise to 60° C. or more, and the deposition rates are 3.2 Å/sec for Nb and 4 Å/sec for Si, which are high deposition rates.

FIG. 13 shows spectroscopic analysis spectrums of deposited Nb₂O₅ and SiO₂ layers, in which a theoretical design value and actual measurement values (BPF1: measured when 1 hour has lapsed after deposition, and BPF2: measured when 24 hours have lapsed after deposition) are shown. The measurement was carried out using a spectrometer (PerkinElmer lambda900).

It can be found that the theoretical design value differs from the actual measurement values at transmittance of 80%. This is responsible for a thickness error caused by a change in the process conditions during deposition. Generally, when the multiple thin films are deposited using E-beam, the measurement

value after the lapse of 1 hour and the measurement value after the lapse of 24 hours are shifted to a long wavelength region on the graph. This shift is responsible for penetration of moisture into voids between the thin films because the deposited thin films are not dense.

However, it can be seen from FIG. 13 that the measurement value after the lapse of 1 hour is identical to the measurement value after the lapse of 24 hours, which means that the deposited thin films are dense.

1. An apparatus for depositing an oxide thin film using sputtering and ion beam deposition, comprising:
a chamber having a substrate holder drum installed therein;
a substrate mounted on the substrate holder drum;
metal targets installed on opposite outer walls of the chamber so as to deposit a metal thin film onto the substrate; and
an ion source gun installed on the chamber and generating oxygen ions for oxidizing the metal thin film,
wherein the ion source gun includes an outer cathode, an inner cathode, an anode between the outer and inner cathodes, and at least one magnet installed to the anode.

2. The apparatus according to claim 1, wherein the magnet is mounted inside the anode of the ion source gun.

3. The apparatus according to claim 1, wherein the anode of the ion source gun has a conductor placed above and in contact with the magnet.

4. The apparatus according to claim 1, wherein the ion source gun has an insulator so that the anode is located on the insulator, spaced apart from the magnet.

5-8. (canceled)

9. The apparatus according to claim 2, wherein the ion source gun is configured so that each of the outer and inner cathodes maintains an angle of 45°±10° with respect to the magnet.

10. The apparatus according to claim 3, wherein the ion source gun is configured so that each of the outer and inner cathodes maintains an angle of 45°±10° with respect to the magnet.

11. The apparatus according to claim 4, wherein the ion source gun is configured so that each of the outer and inner cathodes maintains an angle of 45°±10° with respect to the magnet.

12. The apparatus according to claim 2, wherein the ion source gun is configured so that a distance between the anode and the inner cathode and a distance between the anode and the outer cathode each maintain 10±8 mm.

13. The apparatus according to claim 3, wherein the ion source gun is configured so that a distance between the anode and the inner cathode and a distance between the anode and the outer cathode each maintain 10±8 mm.

14. The apparatus according to claim 4, wherein the ion source gun is configured so that a distance between the anode and the inner cathode and a distance between the anode and the outer cathode each maintain 10±8 mm.

15. The apparatus according to claim 2, wherein the ion source gun is configured so that a distance between the magnet and the inner cathode and a distance between the magnet and the outer cathode each maintain 15±8 mm.

16. The apparatus according to claim 3, wherein the ion source gun is configured so that a distance between the magnet and the inner cathode and a distance between the magnet and the outer cathode each maintain 15±8 mm.

17. The apparatus according to claim 4, wherein the ion source gun is configured so that a distance between the magnet and the inner cathode and a distance between the magnet and the outer cathode each maintain 15±8 mm.

18. The apparatus according to 2, wherein the ion source gun is configured so that gas (O₂) is injected into opposite sides of the anode.

19. The apparatus according to 3, wherein the ion source gun is configured so that gas (O₂) is injected into opposite sides of the anode.

20. The apparatus according to 4, wherein the ion source gun is configured so that gas (O₂) is injected into opposite sides of the anode.
